(19) United States
(12) Patent Application Publication
(10) Pub. No.: US 2023/0108896 A1
(43) Pub. Date: Apr. 6, 2023

(54) PROTECTIVE COVER MEMBER AND MEMBER SUPPLYING SHEET

(71) Applicant: NITTO DENKO CORPORATION, Osaka (JP)

(72) Inventors: Hiroki KIGAMI, Osaka (JP); Takeo INOUE, Osaka (JP); Yoshinori WATANABE, Osaka (JP); Izumi SHIMIZU, Osaka (JP)

(73) Assignee: NITTO DENKO CORPORATION, Osaka (JP)

(21) Appl. No.: 17/910,229

(22) PCT Filed: Mar. 11, 2021
(86) PCT No.: PCT/JP2021/009881

§ 371 Date: Sep. 8, 2022

(30) Foreign Application Priority Data
Mar. 18, 2020 (JP) 2020-047325
Jul. 10, 2020 (JP) 2020-119319

(51) Int. Cl. C09J 183/04; B81B 7/00; C09J 7/38

(52) U.S. Cl. CPC C09J 183/04; B81B 7/0038; C09J 7/38; C09J 2301/124; C09J 2301/302; C09J 2301/312; C09J 2203/326; C09J 2400/226

(57) ABSTRACT

A provided protective cover member is a protective cover member configured to be placed on a face of an object, the face having an opening. The protective cover member includes a laminate, and the laminate includes: a protective membrane having a shape configured to cover the opening when the member is placed on the face; and an adhesive agent layer. The adhesive agent layer includes a cured adhesive layer of a silicone adhesive agent composition including an addition-curable silicone adhesive agent. The above protective cover member is a member reducing deformation thereof and peeling thereof from a placement face at high temperatures, for example, in reflow soldering.

### TECHNICAL FIELD

The present invention relates to a protective cover member configured to be placed on a face of an object, the face having an opening, and a member supplying tape for supplying the member.

### BACKGROUND ART

Protective cover members configured to be placed on a face of an object to prevent entrance of a foreign matter into an opening of the face are known. Generally, a protective cover member includes: a protective membrane that prevents entrance of a foreign matter into an opening when the member is placed on a face having the opening; and an adhesive agent layer that fixes the member to the face. Patent Literature 1 discloses a member including: a porous membrane including polytetrafluoroethylene (hereinafter referred to as “PTFE”) as a main component and allowing gas and/or sound to pass therethrough but blocking a foreign matter such as a water drop from passing therethrough; and a heat-resistant double-sided adhesive sheet placed on a limited region of at least one principal surface of the porous membrane in order to fix the porous membrane to another component. Patent Literature 1 focuses a substrate of the heat-resistant double-sided adhesive sheet configured to fix the member to a surface of a circuit board which is an object to achieve heat resistance of the member at high temperatures in reflow soldering.

### CITATION LIST

### Patent Literature

Patent Literature 1: JP 2007-081881 A

### SUMMARY OF INVENTION

### Technical Problem

Recently, there is a demand for placement of a protective cover member over an opening of a tiny product such as a micro electro mechanical system (hereinafter referred to as “MEMS”). There is also a demand for placement of a protective cover member on a face inside such a product as well as on an outer surface. To satisfy the demands, the area of such a protective membrane has been more and more decreased. Under such circumstances, decreasing the area of an adhesive agent layer that prevents passage of gas and sound, such as decreasing the width of the adhesive agent layer placed in a peripheral portion of the protective membrane, is forced in order to allow passage of gas and/or sound through the protective membrane as much as possible. According to studies by the present inventors, in the case where the area of an adhesive agent layer is decreased, deformation of a protective cover member and peeling of a protective cover member from the above face (placement face) tend to happen at high temperatures, for example, in reflow soldering. The above circumstance is not considered in Patent Literature 1.

The present invention aims to provide a protective cover member reducing deformation thereof and peeling thereof from a placement face at high temperatures, for example, in reflow soldering.

### Solution to Problem

The present invention provides a protective cover member,

the protective cover member being configured to be placed on a face of an object, the face having an opening, the protective cover member including a laminate, wherein

the laminate includes: a protective membrane having a shape configured to cover the opening when the member is placed on the face; and an adhesive agent layer, and

the adhesive agent layer includes a cured adhesive layer of a silicone adhesive agent composition including an addition-curable silicone adhesive agent.

In another aspect, the present invention provides a member supplying sheet including:

a substrate sheet; and

at least one protective cover member placed on the substrate sheet, wherein

the protective cover member is the above protective cover member of the present invention.

### Advantageous Effects of Invention

According to studies by the present inventors, one of the causes of the above-described deformation and peeling is shrinking of an adhesive agent layer at high temperatures. In the protective cover member of the present invention, the adhesive agent layer includes a particular silicone-based cured adhesive layer. The adhesive agent layer does not greatly shrink at high temperatures. Therefore, the above deformation and peeling at high temperatures can be reduced.

### BRIEF DESCRIPTION OF DRAWINGS

FIG. 1A is a cross-sectional view schematically showing an example of a protective cover member of the present invention.

FIG. 1B is a plan view of the protective cover member 1 of FIG. 1A viewed from an adhesive agent layer 3 side.

FIG. 2 is a schematic view showing an example of an embodiment of placing the protective cover member of the present invention on an object.

FIG. 3 is a cross-sectional view schematically showing an example of the protective cover member of the present invention.

FIG. 4A is a cross-sectional view schematically showing an example of the protective cover member of the present invention.

FIG. 4B is a cross-sectional view schematically showing an example of the protective cover member of the present invention.

FIG. 5 is a cross-sectional view schematically showing an example of the protective cover member of the present invention.

FIG. 6 is a cross-sectional view schematically showing an example of the protective cover member of the present invention.

FIG. 7 is a plan view schematically showing an example of a member supplying sheet of the present invention.

FIG. 8 shows appearances of samples of Examples and Comparative Examples having undergone a heating treatment.

### DESCRIPTION OF EMBODIMENTS

Embodiments of the present invention will be described with reference to the drawings. The present invention is not limited to the following embodiments.

[Protective Cover Member]

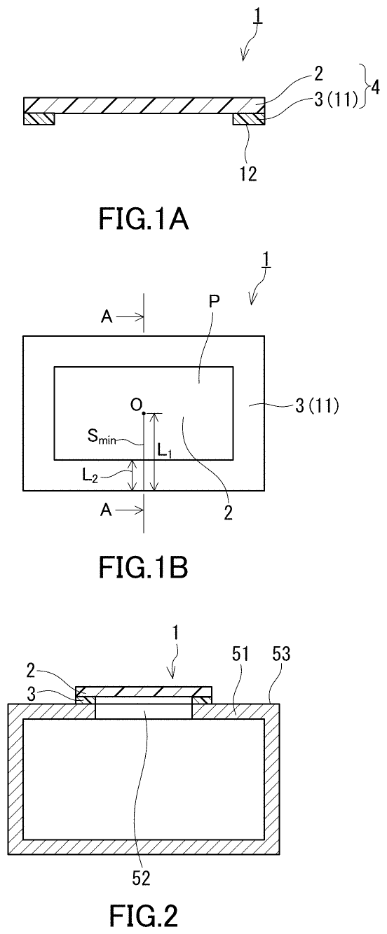

FIGS. 1A and 1B show an example of a protective cover member of the present invention. FIG. 1B is a plan view of the protective cover member 1 of FIG. 1A viewed from an adhesive agent layer 3 side. FIG. 1A shows a cross-section A-A of FIG. 1B. The protective cover member 1 is a member configured to be placed on a face (placement face) of an object, the face having an opening. By placing the protective cover member 1 on the placement face, for example, entrance of a foreign matter into and/or from the opening, i.e., entrance of a foreign matter through the opening, can be prevented. The protective cover member 1 may be a member configured to be placed on a face of an object to prevent entrance of a foreign matter into an opening of the face. The protective cover member 1 includes a laminate 4 including a protective membrane 2 and an adhesive agent layer 3. The protective membrane 2 has a shape configured to cover the opening when the protective cover member 1 is placed on the face. The adhesive agent layer 3 is located on one principal surface side of the protective membrane 2. The adhesive agent layer 3 is joined to the protective membrane 2. The protective cover member 1 can be fixed to the placement face of the object by the adhesive agent layer 3.

The adhesive agent layer 3 includes a cured adhesive layer 11 of a silicone adhesive agent composition A (hereinafter referred to as “composition A”) including an addition-curable silicone adhesive agent. The cured adhesive layer 11 is a cured layer of the composition A and has adhesiveness. The cured adhesive layer 11 is formed by curing the composition A. The adhesive agent layer 3 of FIGS. 1A and 1B is formed of the cured adhesive layer 11. The cured adhesive layer 11 is in contact with the protective membrane 2. Additionally, the cured adhesive layer 11 can form a joining face 12 of the protective cover member 1, the joining face 12 being configured to be joined to a placement face of an object. The degree of shrinking of each of the cured adhesive layer 11 and the adhesive agent layer 3 including the cured adhesive layer 11 is small at high temperatures. Consequently, shrinking-induced deformation of the protective membrane 2, and shrinking-induced peeling of the adhesive agent layer 3 from the protective membrane 2 and/or a placement face can be reduced.

The composition A includes the addition-curable silicone adhesive agent, and preferably includes the addition-curable silicone adhesive agent as a main component. The term “main component” herein refers to a component whose content is highest. The content of the main component is, for example, 50 weight % or more, and may be 60 weight % or more, 70 weight % or more, 80 weight % or more, 90 weight % or more, 95 weight % or more, or even 99 weight % or more. The composition A may be formed of the addition-curable silicone adhesive agent. The composition A preferably does not include a peroxide-curable silicone adhesive agent. A cured adhesive layer of a peroxide-curable silicone adhesive agent greatly shrinks at high temperatures.

It is inferred that a difference between the shrinkage of a cured adhesive layer of an addition-curable silicone adhesive agent at high temperatures and the shrinkage of a cured adhesive layer of a peroxide-curable silicone adhesive agent at high temperatures is attributed to different states of distribution of crosslinking points, the different states being attributed to different reaction mechanisms. In the addition-curable type, addition reaction groups that can serve as crosslinking points are uniformly present in a composition, and three-dimensional crosslinking by a hydrosilane compound having a lot of crosslinking points progresses; therefore, the distribution of crosslinking points in the cured adhesive layer is relatively uniform. On the other hand, in the peroxide-curable type, a reaction progresses in which, among a plurality of functional groups that a silicone molecule can have, a functional group with a randomly and competitively generated radical serves as a crosslinking point; therefore, the positions and the number of crosslinking points differ from one silicone molecule to another and thus crosslinking points are more randomly distributed in the cured adhesive layer. It is inferred that these different states of distribution result in the difference in shrinkage at high temperatures.

The composition A generally includes a silicone compound (component A) having an addition reaction group, a silicone resin (component B), a hydrosilane compound (component C), and a catalyst (component D).

Examples of the silicone compound (component A) having an addition reaction group include organopolysiloxanes having an addition reaction group and partial condensates thereof. The organopolysiloxane may be any of monoorganopolysiloxane, diorganopolysiloxane, and triorganopolysiloxane, and is preferably at least one selected from the group consisting of monoorganopolysiloxane and diorganopolysiloxane, and more preferably diorganopolysiloxane. An organo group in the organopolysiloxane is, for example, a hydrocarbon group having 1 to 8 carbon atoms, preferably a hydrocarbon group having 1 to 4 carbon atoms, and more preferably an alkyl group (may be linear or branched) having 1 to 4 carbon atoms. A typical example of the organo group is a methyl group. One or some of the organo groups may be substituted by a hydroxy group. Examples of the addition reaction group include a monovalent organic group containing an alkenyl group, typical examples of the addition reaction group include a vinyl group and an allyl group, and the addition reaction group is preferably a vinyl group. The addition reaction group is generally present at at least one terminal of a molecule of the component A, and may be present at both terminals thereof. Specific examples of the component A include vinyldimethylpolysiloxane, vinyldiethylpolysiloxane, vinylisopropylpolysiloxane, and vinylphenylmethylsiloxane. The amount of the addition reaction group in the component A is, for example, 0.0005 mol or more and 0.5 mol or less per 100 g of the silicone compound. The component A generally does not have a Q unit (SiO₂) and a Si—H group.

The weight-average molecular weight of the component A is, for example, 100,000 to 1,000,000 and may be 100,000 to 500,000. The component A may be an oily component or a raw-rubber-like component (silicone rubber).

The content of the component A in the composition A is, for example, 20 to 80 weight % and may be 30 to 70 weight %.

The composition A may include two or more components A.

Examples of the silicone resin (component B) include: organopolysiloxanes having the Q unit and at least one unit selected from the group consisting of an M unit (R₃SiO_{1/2}), a D unit (R₂SiO), and a T unit (RSiO_{3/2}); and partial condensates thereof. The symbol Rs in the M unit, the D unit, and the T unit are, for example, each independently a hydrocarbon group having 1 to 8 carbon atoms, preferably a hydrocarbon group having 1 to 4 carbon atoms, and more preferably an alkyl group (which may be linear or branched) having 1 to 4 carbon atoms. A typical example of R is a methyl group. One or some of Rs may be substituted by a hydroxy group. The component B generally does not have an addition reaction group. The component B is preferably, what is called, an MQ resin formed of the M unit and the Q unit. The symbol R in the M unit of the MQ resin may be a methyl group.

A content ratio (molar ratio) between the M unit and the Q unit in the MQ resin is, for example, 0.3:1 to 1.5:1 and may be 0.5:1 to 1.3:1, as expressed as “M unit:Q unit”.

The weight-average molecular weight of the component B is, for example, 1,000 to 10,000 and may be 3,000 to 8,000.

The content of the component B in the composition A is, for example, 20 to 80 weight % and may be 30 to 70 weight %.

The composition A may include two or more components B.

A mix ratio (mass ratio) between the component A and the component B in the composition A is, for example, 20:80 to 80:20 and may be 25:75 to 50:50, as expressed as “component A:component B”.

The hydrosilane compound (component C) is a Si—H group-containing component that reacts with the addition reaction group of the component A to form a crosslinked structure. Examples of the component C include hydrogen organopolysiloxanes and partial condensates thereof. The hydrogen organopolysiloxane may be hydrogen monoorganopolysiloxane and/or hydrogen diorganopolysiloxane. Examples of an organo group are the same as the examples of the organo group of the component A, including the preferable embodiments. One or some of the organo groups may be substituted by a hydroxy group. Specific examples of the component C include hydrogen monomethylpolysiloxane and hydrogen dimethylpolysiloxane, and the component C may be a copolymer of hydrogen monomethylsiloxane and hydrogen dimethylsiloxane.

The weight-average molecular weight of the component C is, for example, 100 to 10,000 and may be 100 to 1,000. The component C may be an oily component or a raw-rubber-like component (silicone rubber).

The component C is preferably added to the composition A so that a molar ratio of the Si—H group in the component C to the addition reaction group, such as a monovalent organic group having an alkenyl group, included in the composition A is, for example, 0.5 to 20, particularly 0.8 to 15.

The composition A may include two or more components C.

The catalyst (component D) is a component accelerating a curing reaction of the composition A. The catalyst is typically a catalyst including a platinum group element and is preferably a platinum-based catalyst. The platinum group element included in the component D stays in the cured adhesive layer 11.

The content of the component D in the composition A is, for example, 5 to 500 ppm (on a weight basis; the same applies hereinafter) and may be 10 to 200 ppm.

The composition A may include an additional component other than those described above as long as the effect of the present invention is achieved. Examples of the additional component include a silicone compound other than the component A, the component B, and the component C, a reaction-controlling agent, an antioxidant, and a ultraviolet absorber.

A commercially-available addition-curable silicone adhesive agent may be used as the addition-curable silicone adhesive agent. An addition-curable silicone adhesive agent not included in the above examples can also be used.

The cured adhesive layer 11 may have a shrinkage X of 15% or less at 260° C. in at least one in-plane direction. The shrinkage X may be 14% or less, 13% or less, 12% or less, 11% or less, or even 10% or less. The lower limit of the shrinkage X is, for example, 0.01% or more. The cured adhesive layer 11 may have a shrinkage X in the above range in at least two or more in-plane directions or may have a shrinkage X in the above range in all in-plane directions. When the composition A is applied to a surface of a base sheet, such as a later-described substrate 13A, in one direction for formation of the cured adhesive layer 11, the cured adhesive layer 11 may have a shrinkage X in the above range in an MD (the direction in which the composition A is applied) and/or a TD (an in-plane direction of the cured adhesive layer 11, the in-plane direction being perpendicular to the MD). The shrinkage X can be determined by the following equation: (D₀−D₁)/D₀×100 (%), where D₀ is a dimension of the cured adhesive layer 11 in the above direction before a heating treatment in which the cured adhesive layer 11 formed on a polyimide substrate (thickness: 25 μm) is maintained, for 1 minute, in a heating bath maintained at 260° C., and D₁ is a dimension of the cured adhesive layer 11 in the above direction after the heating treatment. The dimensions D₀ and D₁ are measured in an environment at a temperature of 25° C.±5° C. and a humidity of 50±5% RH.

The cured adhesive layer 11 has a gel fraction of, for example, 25 to 80 weight %. The gel fraction of the cured adhesive layer 11 is preferably 25 to 65 weight %, 30 to 60 weight %, or even 35 to 55 weight %. When the gel fraction is in the above preferable range, an initial adhesive force (anchoring effect) of the cured adhesive layer 11 to a PTFE membrane and/or an adhesive force of the cured adhesive layer 11 to a PTFE membrane after the heating treatment at 260° C. can be improved. A PTFE membrane such as a stretched porous PTFE membrane can be used as the protective membrane 2. However, PTFE is a substance having a low ability to allow adhesion thereto. When the gel fraction of the cured adhesive agent layer 11 is in the above preferable range in the protective cover member 1 in which the cured adhesive layer 11 and the protective membrane 2 are joined, deformation of the protective cover member 1 and peeling of the protective membrane 2 from the adhesive agent layer 3 at high temperatures are more reliably reduced owing to the improved adhesive force.

The gel fraction of the cured adhesive layer 11 can be determined by the following method. About 0.1 g of a test specimen taken from the cured adhesive layer 11 to be evaluated is wrapped in a stretched porous PTFE membrane (for example, NTF1122 manufactured by Nitto Denko Corporation) having an average pore diameter of 0.2 μm, which is then bound with a kite string to obtain a measurement sample. Next, the weight (pre-immersion weight C) of the measurement sample is measured. The pre-immersion weight C corresponds to the total weight of the test specimen, the stretched porous PTFE membrane, and the kite string. Separately, a wrapping weight B which is the total weight of the stretched porous PTFE membrane and the kite string is measured. The measurement sample is placed in a container filled with toluene and having an inner capacity of 50 mL and is allowed to stand still at 23° C. for 7 days. Thereafter, the inside of the container is washed with ethyl acetate together with the measurement sample. The measurement sample is then taken out, transferred into an aluminum cup, and dried at 130° C. for 2 hours to remove ethyl acetate. Then, the weight (post-immersion weight A) of the measurement sample is measured. The gel fraction can be determined by the following equation: gel fraction (weight %)=(post-immersion weight A−wrapping weight B)/(pre-immersion weight C−wrapping weight B)×100. The weights are measured in an environment at a temperature of 25° C.±5° C. and a humidity of 50±5% RH.

The initial adhesive force of the cured adhesive layer 11 to a PTFE membrane is, for example, 1.5 N/20 mm or more, and may be 1.7 N/20 mm or more, 1.8 N/20 mm or more, 2.0 N/20 mm or more, 2.5 N/20 mm or more, 3.0 N/20 mm or more, 3.5 N/20 mm or more, or even 4.0 N/20 mm or more. The upper limit of the initial adhesive force is, for example, 100 N/20 mm or less. The adhesive force to a PTFE membrane after the heating treatment (at 260° C. for 1 minute) is, for example, 1.5 N/20 mm or more, and may be 1.7 N/20 mm or more, 1.8 N/20 mm or more, 2.0 N/20 mm or more, 2.4 N/20 mm or more, 2.5 N/20 mm or more, 3.0 N/20 mm or more, 3.5 N/20 mm or more, or even 4.0 N/20 mm or more. The upper limit of the adhesive force is, for example, 100 N/20 mm or less.

An elastic modulus (storage modulus G′) of the cured adhesive layer 11 at 250° C. is, for example, 5.0×10⁴ Pa or more and may be 5.5×10⁴ Pa or more, 6.0×10⁴ Pa or more, or even 6.5×10⁴ Pa or more. The upper limit of the elastic modulus at 250° C. is, for example, 1.0×10⁸ Pa or less. The elastic modulus can be measured by the following method using a rheometer. The cured adhesive layer 11 to be measured is cut into pieces, which are laminated such that the resulting laminate has an in-plane area of 75 mm² or more and a thickness of 3 mm or more. A measurement sample is thus obtained. Next, an elastic modulus of the measurement sample at a moment when 250° C. is reached is determined by subjecting the measurement sample to a temperature increase measurement which starts at a temperature of 25° C. and which is performed using a rheometer (for example, Advanced Rheometric Expansion System (ARES) manufactured by Rheometric Scientific Inc.) under the following measurement conditions: shearing mode; frequency of 1 Hz; and temperature increase rate of 5° C./min.

The adhesive agent layer 3 and the cured adhesive layer 11 of FIG. 1B are joined to the protective membrane 2. However, an additional layer may be placed between the adhesive agent layer 3 and the protective membrane 2 and/or between the cured adhesive layer 11 and the protective membrane 2. Shrinking of the cured adhesive layer 11 can influence even the additional layer included in the laminate 4. Therefore, even when the additional layer is placed between the adhesive agent layer 3 and the protective membrane 2 and/or between the cured adhesive layer 11 and the protective membrane 2, the effect of the present invention can be achieved.

FIG. 2 shows an example of an embodiment of placing the protective cover member of FIGS. 1A and 1B on an object. In the example of FIG. 2, the protective cover member 1 is placed on a face 53 of an object 51, the face 53 having an opening 52. The protective cover member 1 is fixed to the face 53 via the adhesive agent layer 3. In this example, the adhesive agent layer 3 (cured adhesive layer 11) forms the joining surface 12 joined to the face 53 of the object 51.

The adhesive agent layer 3 may have a laminate structure as long as including the cured adhesive layer 11. The laminate structure may include two or more adhesive layers, and at least one adhesive layer selected from the two or more adhesive layers or every adhesive layer may be the cured adhesive layer 11.

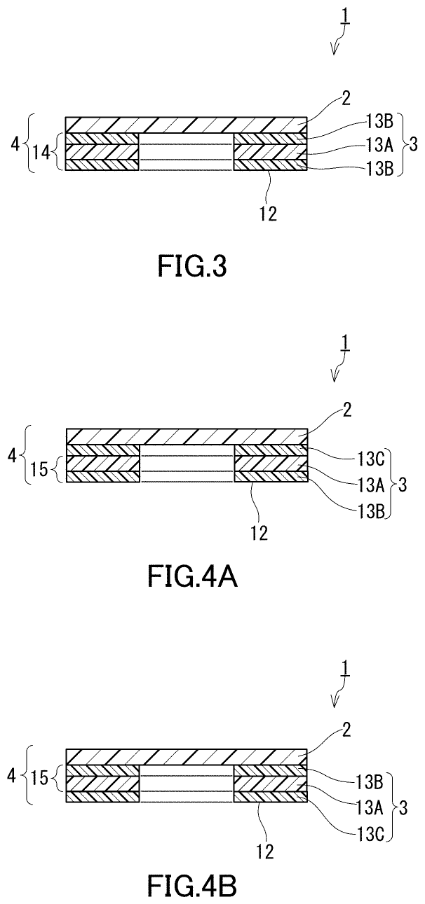

The adhesive agent layer 3 may include an adhesive tape including a substrate and the cured adhesive layer 11 placed on at least one surface of the substrate. The adhesive tape may be a double-sided adhesive tape. FIG. 3 shows an example of such an embodiment. The adhesive agent layer 3 of FIG. 3 is a double-sided adhesive tape 14 including a substrate 13A and two adhesive layers 13B each provided on a surface of the substrate 13A. One of the adhesive layers 13B is in contact with the protective membrane 2. The other adhesive layer 13B forms the joining surface 12 of the protective cover member 1. At least one selected from the two adhesive layers 13B is the cured adhesive layer 11, and both of them may be the cured adhesive layer 11. The double-sided adhesive tape 14 may be a substrate-less tape not having the substrate 13A.

The adhesive agent layer 3 of each of FIGS. 4A and 4B is a laminate structure in which an adhesive layer 13C and a single-sided adhesive tape 15 including the substrate 13A and the adhesive layer 13B provided on one side of the substrate 13A are combined. In the adhesive agent layer 3 of FIG. 4A, the adhesive layer 13B of the single-sided adhesive tape 15 forms the joining surface 12, and the adhesive layer 13C is in contact with the protective membrane 2. In the adhesive agent layer 3 of FIG. 4B, the adhesive layer 13B of the single-sided adhesive tape 15 is in contact with the protective membrane 2, and the adhesive layer 13C forms the joining surface 12. The adhesive layer 13B or the adhesive layer 13C may be the cured adhesive layer 11, and both the adhesive layer 13B and the adhesive layer 13C may be the cured adhesive layers 11. Additionally, the adhesive layer 13C may have the same configuration (including an embodiment of having the above laminate structure) as that of the adhesive agent layer 3, and may be the above-described double-sided adhesive tape 14.

The substrate 13A is, for example, a film, non-woven fabric, or foam made of a resin, metal, or composite material thereof. Examples of the resin include polyolefins such as polyethylene and polypropylene, polyesters such as polyethylene terephthalate (PET), silicone resins, polycarbonates, polyimides, polyamide-imides, polyphenylene sulfide, polyetheretherketone (PEEK), and fluorine resins. Examples of the fluorine resins include polytetrafluoroethylene (PTFE), tetrafluoroethylene-perfluoroalkyl vinyl ether copolymer (PFA), tetrafluoroethylene-hexafluoropropylene copolymer (FEP), and tetrafluoroethylene-ethylene copolymer (ETFE). Examples of the metal include stainless steel and aluminum. However, the resin and the metal are not limited to the above examples.

The substrate 13A may include a heat-resistant material. In this case, the protective cover member 1 can be used more reliably at high temperatures depending on the materials of the other layers of the protective cover member 1. Examples of the heat-resistant material include a metal and a heat-resistant resin. The heat-resistant resin typically has a melting point of 150° C. or higher. The heat-resistant resin may have a melting point of 160° C. or higher, 200° C. or higher, 250° C. or higher, 260° C. or higher, or even 300° C. or higher. Examples of the heat-resistant resin include a silicone resin, a polyimide, a polyamide-imide, polyphenylene sulfide, PEEK, and a fluorine resin. The fluorine resin may be PTFE. PTFE is excellent particularly in heat resistance.

The adhesive agent layer 3 of FIG. 1B is placed in a partial region of the protective membrane 2 when viewed perpendicular to the principal surface of the protective membrane 2. The adhesive agent layer 3 of FIG. 1B is in the shape of a peripheral portion of the protective membrane 2, specifically, in the shape of a frame, when viewed perpendicular to the principal surface of the protective membrane 2. In this case, more favorable passage of gas and/or sound can be achieved in a region P, where the adhesive agent layer 3 is not formed, of the protective membrane 2 than in a region where the adhesive agent layer 3 is formed. However, the shape of the adhesive agent layer 3 is not limited to the above example.

The region P of the protective membrane 2 has an area of, for example, 20 mm² or less. The protective cover member 1 including the region P having an area in this range is, for example, suitable for being placed on a MEMS or circuit board that normally has a small-diameter opening. The lower limit of the area of the region P is, for example, 0.008 mm² or more. However, the area of the region P may be beyond the above range depending on the type of an object on which the protective cover member 1 is placed.

The thickness of the adhesive agent layer 3 is, for example, 10 to 200 μm.

The protective membrane 2 may be gas-impermeable in a thickness direction thereof or may have gas permeability in the thickness direction. In the case where the protective membrane 2 has gas permeability in the thickness direction, placement of the protective cover member 1 allows, for example, passage of gas through an opening of an object while entrance of a foreign matter through the opening of the object is prevented. By allowing passage of gas, for example, adjustment of pressure and reduction of pressure variability can be achieved through the opening of the object. An example of reducing pressure variability is shown hereinafter. Sometimes, a heat treatment such as reflow soldering is performed with a semiconductor device placed to cover one opening of a through hole provided in a circuit board. With the protective cover member 1 placed to cover the other opening of the through hole, entrance of a foreign matter into the device through the through hole can be reduced in the heat treatment. The protective membrane 2 having gas permeability in the thickness direction reduces a heat-induced increase in pressure in the through hole and can thereby prevent damage to the device by the pressure increase. Examples of the semiconductor device include MEMSs such as microphones, pressure sensors, and acceleration sensors. These devices have an opening allowing gas or sound to pass therethrough, and can be placed on a circuit board such that the opening faces a through hole provided in the circuit board. The protective cover member 1 may be placed on a manufactured semiconductor device such that the protective cover member 1 covers an opening of the manufactured semiconductor device. In the case where the protective membrane 2 has gas permeability in the thickness direction, the protective cover member 1 placed on an object can function, for example, as a gas-permeable member allowing passage of gas through an opening of the object while preventing entrance of a foreign matter through the opening and/or a sound-permeable member allowing passage of sound through an opening of the object while preventing entrance of a foreign matter through the opening. It should be noted that even in the case where the protective membrane 2 is gas-impermeable in the thickness direction, it is possible to transmit sound by vibration of the protective membrane 2, and therefore the protective cover member 1 placed on an object can function as a sound-permeable member.

The protective membrane 2 having gas permeability in the thickness direction has a gas permeability of, for example, 100 sec/100 mL or less as expressed in terms of a gas permeability (Gurley air permeability) obtained according to Method B (Gurley method) of gas permeability measurement specified in JIS L 1096.

The protective membrane 2 may be waterproof. The protective cover member 1 including the protective membrane 2 being waterproof can function, for example, as a waterproof gas-permeable member and/or a waterproof sound-permeable member after placed on an object. The protective membrane 2 being waterproof has a water entry pressure of, for example, 5 kPa or more. The water entry pressure is determined according to Method A (low water pressure method) or Method B (high water pressure method) of the water resistance test defined in JIS L 1092.

Examples of the material forming the protective membrane 2 include a metal, a resin, and a composite material thereof.

Examples of the resin and metal that can form the protective membrane 2 are the same as the examples of the resin and metal that can form the substrate 13A. However, the resin and metal that can form the protective membrane 2 are not limited to the above examples.

The protective membrane 2 may be formed of a heat-resistant material. In this case, applicability of the protective membrane to treatment, such as reflow soldering, under high temperatures can be ensured depending on the materials of the other layers of the protective cover member 1. Examples of the heat-resistant material are as described above in the description of the substrate 13A. In one example, the protective membrane 2 may include a PTFE membrane.

The protective membrane 2 having gas permeability in the thickness direction may include a stretched porous membrane. The stretched porous membrane may be a stretched porous fluorine resin membrane, and particularly a stretched porous PTFE membrane. The stretched porous PTFE membrane is normally formed by stretching a cast membrane or a paste extrusion containing PTFE particles. The stretched porous PTFE membrane is formed of fine PTFE fibrils and can have a node in which PTFE is more highly aggregated than in the fibrils. With the stretched porous PTFE membrane, it is possible to achieve both a high capability of preventing entrance of a foreign matter and a high gas permeability. A known stretched porous membrane can be used as the protective membrane 2.

The stretched porous membrane is likely to shrink at high temperatures. Therefore, when the protective membrane 2 includes the stretched porous membrane, particularly when the cured adhesive layer 11 is in contact with the protective membrane 2, the effect of the present invention, i.e., reducing deformation of the protective cover member 1 and peeling of the protective cover member 1 from a placement face at high temperatures, is more advantageous.

The protective membrane 2 having gas permeability in the thickness direction may include a perforated membrane in which a plurality of through holes connecting both principal surfaces of the membrane are formed. The perforated membrane may be a membrane formed by providing a plurality of through holes to an original membrane, such as an imperforate membrane, having a non-porous matrix structure. The perforated membrane may have no other ventilation paths in the thickness direction than the plurality of through holes. The through hole may extend in the thickness direction of the perforated membrane or may be a straight hole linearly extending in the thickness direction. An opening of the through hole may have the shape of a circle or an ellipse when viewed perpendicular to a principal surface of the perforated membrane. The perforated membrane can be formed, for example, by laser processing of the original membrane or by ion beam irradiation of the original membrane and subsequent perforation of the resulting membrane by chemical etching.

The protective membrane 2 having gas permeability in the thickness direction may include a non-woven fabric, a woven fabric, a mesh, or a net.

The protective membrane 2 is not limited to the above examples.

The protective membrane 2 of FIG. 1B has the shape of a rectangle when viewed perpendicular to the principal surface of the protective membrane 2. However, the shape of the protective membrane 2 is not limited to the above example, and may be, for example, a polygon such as a square or a rectangle, a circle, or an ellipse when viewed perpendicular to the principal surface thereof. The polygon may be a regular polygon. A corner of the polygon may be rounded.

The thickness of the protective membrane 2 is, for example, 1 to 100 μm.

The protective membrane 2 has an area of, for example, 175 mm² or less, and may have an area of 150 mm² or less, 125 mm² or less, 100 mm² or less, 75 mm² or less, 50 mm² or less, 25 mm² or less, 20 mm² or less, 15 mm² or less, 10 mm² or less, or even 7.5 mm² or less. The protective cover member 1 including the protective membrane 2 having an area in the above range is, for example, suitable for being placed on a circuit board or MEMS that normally has a small-diameter opening. The lower limit of the area of the protective membrane 2 is, for example, 0.20 mm² or more. However, the area of the protective membrane 2 may be larger depending on the type of an object on which the protective cover member 1 is placed.

The adhesive agent layer 3 of FIG. 1B is placed in the peripheral portion of the protective membrane 2 when viewed perpendicular to the principal surface of the protective membrane 2. In this case, when viewed perpendicular to the principal surface of the protective membrane 2, a ratio L₂/L₁ may be 0.5 or less, 0.3 or less, 0.2 or less, or even 0.1 or less, where L₁ is a length of a shortest line segment Sₘᵢₙ of line segments extending from a center of the protective membrane 2 to a perimeter of the protective membrane 2, and L₂ is a length of a portion of the shortest line segment Sₘᵢₙ, the portion lying over the adhesive agent layer 3. The lower limit of the ratio L₂/L₁ is, for example, 0.05 or more. The lower the ratio L₂/L₁ is, the greater the influence of shrinking of the adhesive agent layer 3 on the protective cover member 1 is, and, particularly, the more likely the adhesive agent layer 3 is to be peeled from the protective membrane 2 and/or a placement face. Therefore, when the ratio L₂/L₁ is in the above range, the effect of the present invention is more advantageous. The center O of the protective membrane 2 can be determined as a center of gravity of the shape of the protective membrane 2, the shape being defined when viewed perpendicular to the principal surface of the protective membrane 2.

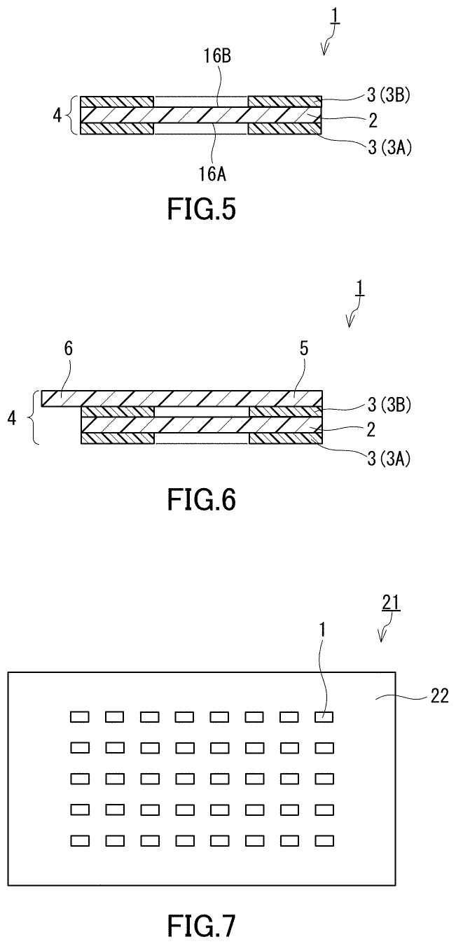

The laminate 4 may include a first adhesive agent layer positioned on a first principal surface side of the protective membrane 2 and a second adhesive agent layer positioned on a second principal surface side of the protective membrane 2, the first principal surface and the second principal surface being opposite to each other. In this case, for example, the laminate 4 can be placed on a face of an object owing to at least one adhesive agent layer selected from the first and the second adhesive agent layers, and it is possible to place an additional layer on the other adhesive agent layer or to join the other adhesive agent layer to, for example, an optional member and/or surface. At least one adhesive agent layer selected from the first and the second adhesive agent layers may be the adhesive agent layer 3 including the cured adhesive layer 11. As shown in FIG. 5, the first adhesive agent layer positioned on a first principal surface 16A side of the protective membrane 2 and the second adhesive agent layer positioned on a second principal surface 16B side of the protective membrane 2 each may be the adhesive agent layer 3 (3A or 3B) including the cured adhesive layer 11. When the first and second adhesive agent layers are each the adhesive agent layer 3, reduction of deformation of the protective cover member 1 and peeling of the protective cover member 1 from a placement face at high temperatures are more reliably achieved.

The shape of the adhesive agent layer 3B of FIG. 5 is the same as that of the adhesive agent layer 3A when viewed perpendicular to the principal surface of the protective membrane 2. In this case, more favorable passage of gas and/or sound can be achieved in a region Q, where the adhesive agent layer 3B is not formed, of the protective membrane 2 than in a region where the adhesive agent layer 3B is formed. However, the shape of the adhesive agent layer 3B is not limited to the above example. The adhesive agent layer 3B may have a different shape from that of the adhesive agent layer 3A when viewed perpendicular to the principal surface of the protective membrane 2. The area of the region Q can be in the same range as that of the region P. The area of the region Q may be the same as that of the region P.

The laminate 4 included in the protective cover member 1 may include a layer other than the protective membrane 2 and the adhesive agent layer 3. FIG. 6 shows an example of the protective cover member 1 including an additional layer.

The laminate 4 of FIG. 6 is the same as the laminate 4 of FIG. 5, except that the laminate 4 of FIG. 6 further includes a cover film 5 coveting the protective membrane 2 on the second principal surface 16B side (the adhesive agent layer 3B side) of the protective membrane 2. The cover film 5 is placed on the adhesive agent layer 3B. An additional layer may be placed between the adhesive agent layer 3B and the cover film 5. The cover film 5 functions as a protective film protecting the protective membrane 2 until the protective cover member 1 is placed on an object, for example. The cover film 5 may be peeled off after the protective cover member 1 is placed on an object. The cover film 5 may cover the entire protective membrane 2 or may cover a part of the protective membrane 2 when viewed perpendicular to the principal surface of the protective membrane 2.

The cover film 5 of FIG. 6 has a tab 6 protruding outward more than the perimeter of the protective membrane 2 when viewed perpendicular to the principal surface of the protective membrane 2. The tab 6 can be used to peel the cover film 5 off. However, the shape of the cover film 5 is not limited to the above examples.

Examples of the material forming the cover film 5 include a metal, a resin, and a composite material thereof. Specific examples of the material that can form the cover film 5 are the same as the specific examples of the material that can form the substrate 13A.

The thickness of the cover film 5 is, for example, 200 to 1,000 μm.

The protective cover member 1 of FIGS. 1A and 1B has the shape of a rectangle when viewed perpendicular to the principal surface of the protective membrane 2. However, the shape of the protective cover member 1 is not limited to the above example. The shape thereof may be a polygon including a square and a rectangle, a circle, and an ellipse when viewed perpendicular to the principal surface of the protective membrane 2. The polygon may be a regular polygon. A corner of the polygon may be rounded.

The area of the protective cover member 1 (the area defined when the member 1 is viewed perpendicular to the principal surface of the protective membrane 2) is, for example, 175 mm² or less, and may be 150 mm² or less, 125 mm² or less, 100 mm² or less, 75 mm² or less, 50 mm² or less, 25 mm² or less, 20 mm² or less, 15 mm² or less, 10 mm² or less, or even 7.5 mm² or less. The protective cover member 1 having an area in the above range is, for example, suitable for being placed on a circuit board or MEMS that normally has a small-diameter opening. The lower limit of the area of the protective cover member 1 is, for example, 0.20 mm² or more. However, the area of the protective cover member 1 may be larger depending on the type of an object on which the protective cover member 1 is placed. It should be noted that the smaller the area of the protective cover member 1 is, the more likely deformation thereof and peeling thereof from a placement face at high temperatures are to happen. Therefore, when the protective cover member 1 has an area in the above range, the effect of the present invention is particularly advantageous.

Examples of an object on which the protective cover member 1 is placed include semiconductor devices, such as MEMSs, and circuit boards. In other words, the protective cover member 1 may be a member for a semiconductor device, circuit board, or MEMS and may be configured to be placed on an object which is a semiconductor device, circuit board, or MEMS. The MEMS may be a non-encapsulated device having a ventilation hole on a surface of its package. Examples of the non-encapsulated MEMS include various sensors detecting the atmospheric pressure, humidity, gas, air flow, and the like and electroacoustic transducer elements such as speakers and microphones. Moreover, examples of the object are not limited to manufactured semiconductor devices and manufactured circuit boards, and the object may be an intermediate product of a semiconductor device or a circuit board in a manufacturing step. In this case, the protective cover member 1 can protect the intermediate product in the manufacturing step. Examples of the manufacturing step include a reflow soldering step, dicing step, bonding step, and mounting step. The manufacturing step, including the reflow soldering step, may be a step performed at high temperatures. The term “high temperatures” as used herein is, for example, 200° C. or higher, and may be 220° C. or higher, 240° C. or higher, or even 260° C. or higher. The reflow soldering step is normally performed at about 260° C. However, the object is not limited to the above examples.

A face of an object on which the protective cover member 1 can be placed is typically an outer surface of the object. The face may be a face inside the object. The face may be a flat face or a curved face. An opening of the object may be an opening of a recessed portion or an opening of a through hole.

The protective cover member 1 can be manufactured, for example, by laminating the protective membrane 2 and the adhesive agent layer 3.

[Member Supplying Sheet]

FIG. 7 shows an example of a member supplying sheet of the present invention. A member supplying sheet 21 shown in FIG. 7 includes a substrate sheet 22 and two or more protective cover members 1 placed on the substrate sheet 22. The member supplying sheet 21 is a sheet for supplying the protective cover member 1. With the use of the member supplying sheet 21, the protective cover member 1 can be effectively supplied, for example, in a step of placing the member 1 on a face of an object.

In the example shown in FIG. 7, two or more protective cover members 1 are placed on the substrate sheet 22. The number of the protective cover members 1 placed on the substrate sheet 22 may be one.

In the example shown in FIG. 7, two or more protective cover members 1 are regularly placed on the substrate sheet 22. More specifically, when viewed perpendicular to the surface of the substrate sheet 22, the protective cover members 1 are placed such that a center of each protective cover member 1 is at an intersection (lattice point) of a rectangular lattice. However, the arrangement of the regularly placed protective cover members 1 is not limited to the above example. The protective cover members 1 may be regularly placed such that the center of each protective cover member 1 is at an intersection of any of various lattices such as a square lattice, an orthorhombic lattice, or a rhombic lattice. However, the embodiment of placing the protective cover members 1 is not limited to the above example. For example, the protective cover members 1 may be placed in a staggered pattern when viewed perpendicular to the surface of the substrate sheet 22. The center of the protective cover member 1 can be determined as a center of gravity of the shape of the member 1, the shape being defined when viewed in perpendicular to the surface of the substrate sheet 22.

Examples of the material forming the substrate sheet 22 include paper, a metal, a resin, and a composite material thereof. Examples of the metal include aluminum and stainless steel. Examples of the resin include a polyester such as PET and a polyolefin such as polyethylene and polypropylene. However, the material forming the substrate sheet 22 is not limited to the above examples.

The protective cover member 1 may be placed on the substrate sheet 22 via an adhesive layer (for example, the adhesive agent layer 3) of the member 1. In this case, a placement face of the substrate sheet 22 on which the protective cover member 1 is placed may have been subjected to release treatment for improving ease of release from the substrate sheet 22. The release treatment can be performed by a known technique.

The protective cover member 1 may be placed on the substrate sheet 22 with an adhesive layer, typically a low-adhesive layer, interposed therebetween, the adhesive layer being provided on the placement face of the substrate sheet 22 on which the protective cover member 1 is placed.

The thickness of the substrate sheet 22 is, for example, 1 to 200 μm.

The substrate sheet 22 of FIG. 7 is in the form of a sheet having a rectangular shape. The shape of the substrate sheet 22 in the form of a sheet is not limited to the above example, and may be a polygon such as a square or a rectangle, a circle, an ellipse, or the like. When the substrate sheet 22 is in the form of a sheet, the member supplying sheet 21 can be distributed and used in the form of a sheet. The substrate sheet 22 may be in the form of a strip. In this case, the member supplying sheet 21 is also in the form of a strip. The member supplying sheet 21 in the form of a strip can be distributed in the form of a wound body wound around a winding core.

The member supplying sheet 21 can be manufactured by placing the protective cover member 1 on a surface of the substrate sheet 22.

### EXAMPLES

Hereinafter, the present invention will be described more specifically by way of examples. The present invention is not limited to examples shown below.

First, methods for evaluating cured adhesive layers (in Comparative Example 4, an acrylic adhesive layer. The same applies hereinafter) will be described.

[Gel Fraction]

Gel fractions of the cured adhesive layers were determined by the above method. The temperature of a measurement environment was 25° C., and the humidity thereof was 50% RH.

[Elastic Modulus at 250° C.]

Storage moduli (250° C.) of the cured adhesive layers were determined by the above method. Advanced Rheometric Expansion System (ARES) manufactured by Rheometric Scientific Inc. was used as a rheometer. Each measurement sample was circular, the in-plane area thereof was 78.5 mm², and the thickness thereof was 5 mm.

[Shrinkage X at 260° C.]

Shrinkages X at 260° C. of the cured adhesive layers were determined in the following manner. Samples B (in the shape of a square 1.7 mm on a side; having a three-layered structure composed of “cured adhesive layer/polyimide substrate (thickness: 25 μm)/cured adhesive layer”) produced in Examples and Comparative Examples were each subjected to a heating treatment in which the sample B was maintained, for 1 minute, in a heating bath maintained at 260° C. After the treatment, the sample was left to cool to 25° C. The two cured adhesive layers were each measured for minimum dimensions Dₘᵢₙ in two directions thereof, namely, the MD and the TD. The minimum dimensions Dₘᵢₙ in each direction of the two cured adhesive layers sandwiching the polyimide substrate were averaged, and the average was determined as a dimension D₁ in the direction after the heating treatment. The shrinkage X (%) was calculated from the determined D₁ by the following equation: shrinkage X=(1.7−D₁)/1.7×100 (%). The minimum dimension Dₘᵢₙ was determined by image analysis of an enlarged image (at a magnification of 47 times) obtained using an optical microscope. The measurement of the minimum dimension Dₘᵢₙ was performed at a temperature of 25° C. and a humidity of 50% RH.

[Adhesive Force to PTFE Membrane]

Initial adhesive forces of the cured adhesive layers to a PTFE membrane and adhesive forces thereof after the heating treatment (at 260° C. for 1 minute) were determined in the following manner by a 180° peel test.

Samples A (in the shape of a step having a three-layered structure composed of “cured adhesive layer/polyimide substrate (thickness: 25 μm)/cured adhesive layer” and having a width of 20 mm and a length of 150 mm) produced in Examples and Comparative Examples were each adhered to a surface of a rectangular fixing plate (made of stainless steel) via one of the cured adhesive layers, the fixing plate having a greater length and width than those of the sample A, the fixing plate being so thick that the fixing plate does not deform during the test. The sample A was adhered such that the long and short sides of the sample A were respectively parallel to the long and short sides of the fixing plate. Next, a strip-shaped PTFE membrane (a microporous membrane having an average pore diameter of 0.5 μm or less and a porosity of 40% and having the shape of a strip having a thickness of 10 μm, a width of 50 mm, a length of 150 mm) was adhered to the sample A such that the PTFE membrane and the other cured adhesive layer were in contact with each other. When a microporous membrane having an average pore diameter of 0.5 μm or less and a porosity of about 30 to 50% is used, a cohesive failure of the PTFE membrane does not occur in the peel test. In addition, the above microporous membrane is used taking a case of joining a porous membrane to the cured adhesive layer into account, and a state of contact between the cured adhesive layer and a porous membrane can be reproduced as appropriate with the above microporous membrane. For these reasons, the adhesive force to the PTFE membrane can be measured as appropriate using the above microporous membrane. As to the method for measuring the average pore diameter of a PTFE membrane, a method described in ASTM F316-86 commonly prevails, and an automated measurement apparatus (for example, Perm Porometer available from Porous Materials Inc., US) can be used for the measurement. The porosity of the PTFE membrane can be determined by the following equation: porosity (%)={1−(mass of membrane [g]/(thickness of membrane [cm]×area of membrane [cm²]×true density of PTFE))}×100. The true density of PTFE is 2.18 g/cm².

The PTFE membrane used in the peel test was produced in the following manner. To a PTFE dispersion (concentration of PTFE powder: 40 mass %; average particle diameter of PTFE powder: 0.2 μm; containing 6 parts by mass of a nonionic surfactant with respect to 100 parts by mass of PTFE) was added 1 part by mass of a fluorine-based surfactant (MEGAFACE F-142D manufactured by DIC CORPORATION) with respect to 100 parts by mass of PTFE. Next, a strip-shaped polyimide film (thickness: 125 μm) was immersed in and pulled up from the PTFE dispersion to form a coating film formed of the PTFE dispersion on the polyimide film. The thickness of the coating film was controlled to 20 μm using a measuring bar. Subsequently, the coating film was heated at 100° C. for 1 minute and then at 390° C. for another 1 minute to evaporate and remove water contained in the dispersion and to bind the remaining PTFE particles to each other. After the above immersion and heating were repeated two more times, the resulting original PTFE membrane (thickness: 25 μm) was peeled off from the polyimide film. Next, the original PTFE membrane obtained was rolled at a rolling ratio of 2.5 in the MD, and then stretched at a stretching ratio of 2.0 in the TD using a tenter-type stretching machine to obtain the above PTFE membrane. A roll calendering apparatus was used for the rolling, and the temperature of the rolls was set at 170° C. The stretching temperature was 170° C.

The sample A and the PTFE membrane were adhered such that the PTFE membrane entirely covered the sample A and a long side of the sample A and that of the PTFE membrane were parallel to each other. After that, a manual roller (defined in JIS Z 0237: 2009 and having a mass of 2 kg) for press-bonding the PTFE membrane, the sample A, and the fixing plate was moved back and forth once with the fixing plate side down. Subsequently, one short side of the fixing plate was fixed to an upper chuck of a tensile test apparatus, and an end portion of the PTFE membrane on the upper chuck side was peeled from the sample A, folded back at 180°, and fixed to a lower chuck of the tensile test apparatus. A 180° peel test in which the PTFE membrane was peeled off the sample A was then performed. The tensile speed is 300 mm/min. For a higher measurement accuracy, measurement values for the first 20 mm length were ignored after the start of the test. Then, measurement values of the adhesive force for an at least 60 mm length peeled off the sample A were averaged, and the average was employed as an adhesive force (unit: N/20 mm) of the cured adhesive layer. The peel test was performed in an environment at a temperature of 25° C. and a humidity of 50% RH. The above test was performed before and after the heating treatment to determine the adhesive force (initial adhesive force) before the heating treatment and the adhesive force after the heating treatment. The heating treatment was performed by maintaining the sample A for 1 minute in a heating bath maintained at 260° C.

### Example 1

A mixture (composition a) of 100 parts by weight of KR3700 manufactured by Shin-Etsu Chemical Co., Ltd. and 0.05 parts by weight of a platinum catalyst (CAT-PL-50T manufactured by Shin-Etsu Chemical Co., Ltd.) was prepared as the addition-curable silicone adhesive agent composition A. KR3700 includes dimethylpolysiloxane as a principal component A, an MQ resin as a principal component B, and hydrogen dimethylpolysiloxane as a principal component C. KR3700 does not include a peroxide-curable silicone adhesive agent.

Next, the composition a was applied in one direction to both principal surfaces of a polyimide substrate (in the shape of a strip having a thickness of 25 μm, a width of 20 mm, and a length of 150 mm). The polyimide substrate and the coating films as a whole were heated at 130° C. for 2 minutes to cure the coating films. A sample A having a three-layered structure composed of “cured adhesive layer/polyimide substrate/cured adhesive layer” was obtained in this manner. The composition a was applied using an applicator so that each coating film would have a thickness of 30 μm after cured. The composition a was applied to the principal surfaces of the polyimide substrate in the same direction. The sample A was cut into a square 1.7 mm on a side to obtain a sample B. The directions of the sides of the square were the MD (the direction in which the composition a was applied) or the TD (an in-plane direction of the cured adhesive layer, the in-plane direction being perpendicular to the MD) of the cured adhesive layer.

### Example 2

A sample A (strip) and a sample B (square) of Example 2 were obtained in the same manner as in Example 1, except that a mixture of 100 parts by weight of X-40-3240 manufactured by Shin-Etsu Chemical Co., Ltd. and 0.05 parts by weight of a platinum catalyst (CAT-PL-50T manufactured by Shin-Etsu Chemical Co., Ltd.) was used as the addition-curable silicone adhesive agent composition A. X-40-3240 includes dimethylpolysiloxane as a principal component A, an MQ resin as a principal component B, and hydrogen dimethylpolysiloxane as a principal component C. X-40-3240 does not include a peroxide-curable silicone adhesive agent.

### Example 3

A sample A (strip) and a sample B (square) of Example 3 were obtained in the same manner as in Example 1, except that a mixture of 75 parts by weight of KR3700 manufactured by Shin-Etsu Chemical Co., Ltd., 25 parts by weight of KR3704 manufactured by Shin-Etsu Chemical Co., Ltd., and 0.05 parts by weight of a platinum catalyst (CAT-PL-50T manufactured by Shin-Etsu Chemical Co., Ltd.) was used as the addition-curable silicone adhesive agent composition A. KR3704 includes dimethylpolysiloxane as a principal component A, an MQ resin as a principal component B, and hydrogen dimethylpolysiloxane as a principal component C. KR3704 does not include a peroxide-curable silicone adhesive agent.

### Example 4

A sample A (strip) and a sample B (square) of Example 4 were obtained in the same manner as in Example 1, except that a mixture of 25 parts by weight of KR3700 manufactured by Shin-Etsu Chemical Co., Ltd., 75 parts by weight of KR3704 manufactured by Shin-Etsu Chemical Co., Ltd., and 0.05 parts by weight of a platinum catalyst (CAT-PL-50T manufactured by Shin-Etsu Chemical Co., Ltd.) was used as the addition-curable silicone adhesive agent composition A.

### Comparative Example 1

A sample A (strip) and a sample B (square) of Comparative Example 1 were obtained in the same manner as in Example 1, except that a peroxide-curable silicone adhesive agent composition (SH4280 (peroxide amount: 1.2 parts by weight) manufactured by Dow Corning Toray Co., Ltd.) was used instead of the addition-curable silicone adhesive agent composition A. However, the curing conditions of the coating films were 200° C. and 3 minutes.

### Comparative Example 2

A sample A (strip) and a sample B (square) of Comparative Example 2 were obtained in the same manner as in Example 1, except that a peroxide-curable silicone adhesive agent composition (SH4280 (peroxide amount: 2.4 parts by weight) manufactured by Dow Corning Toray Co., Ltd.) was used instead of the addition-curable silicone adhesive agent composition A. However, the curing conditions of the coating films were 200° C. and 3 minutes.

### Comparative Example 3

A sample A (strip) and a sample B (square) of Comparative Example 3 were obtained in the same manner as in Example 1, except that a peroxide-curable silicone adhesive agent composition (KR101-10 (peroxide amount: 2.4 parts by weight) manufactured by Shin-Etsu Chemical Co., Ltd.) was used instead of the addition-curable silicone adhesive agent composition A. However, the curing conditions of the coating films were 200° C. and 3 minutes.

### Comparative Example 4

A sample A (strip) and a sample B (square) of Comparative Example 4 were obtained in the same manner as in Example 1, except that an acrylic adhesive composition (No. 5919 manufactured by Nitto Denko Corporation) was used instead of the addition-curable silicone adhesive agent composition A. However, the coating films were dried by heating at 120° C. for 3 minutes instead of the curing after the application. The adhesive agent composition was applied so that each coating film would have a thickness of 50 μm after dried.

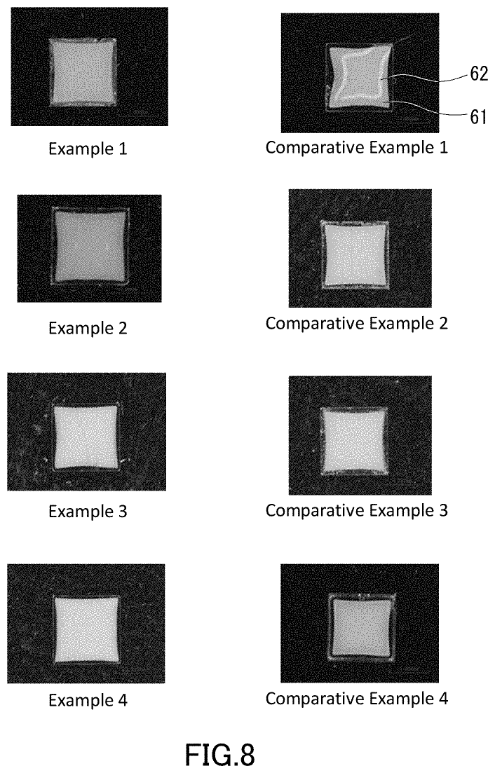

Tables 1A and 1B show the evaluation results. FIG. 8 shows appearances of the samples B of Examples and Comparative Examples having undergone the heating treatment (at 260° C. for 1 minute) performed for evaluation of the shrinkage X.

TABLE 1A

| | | Example 1 | Example 2 | Example 3 | Example 4 |
|---|---|---|---|---|---|
| Type of adhesive layer | | Cured layer of addition-curable silicone | | | |
| | | adhesive agent composition | | | |
| Thickness (μm) | | 30 | 30 | 30 | 30 |
| Gel fraction (weight %) | | 35 | 43 | 52 | 77 |
| Elastic modulus (Pa) at 250° C. | | 6.6 × 10⁴ | — | — | — |
| Shrinkage X (%) by | MD | 12 | 13 | 10 | 9 |
| heating treatment at | TD | 15 | 13 | 11 | 10 |
| 260° C. for 1 minute | | | | | |

| | | | | | |
|---|---|---|---|---|---|
| Adhesive force | Initial | 4.1 | 2.2 | 1.8 | 0.1 |
| (N/20 mm) to | After heating | 4.4 | 2.4 | 2.4 | 0.1 |
| PTFE | treatment at | | | | |
| | 260° C. for 1 minute | | | | |

TABLE 1B

| | | Comparative | Comparative | Comparative | Comparative |
|---|---|---|---|---|---|
| | | Example 1 | Example 2 | Example 3 | Example 4 |
| Type of adhesive layer | | Cured layer of peroxide-curable silicone | | | Acrylic |
| | | adhesive agent composition | | | adhesive |
| | | | | | layer |
| Thickness (μm) | | 30 | 30 | 30 | 50 |
| Gel fraction (weight %) | | 40 | 46 | 55 | — |
| Elastic modulus (Pa) at 250° C. | | 4.3 × 10⁴ | — | — | 6.6 × 10⁴ |
| Shrinkage X (%) by | MD | 21 | 16 | 17 | 20 |
| heating treatment at | TD | 20 | 17 | 19 | 18 |
| 260° C. for 1 minute | | | | | |

| | | | | | |
|---|---|---|---|---|---|
| Adhesive force | Initial | 3.3 | 3.0 | 2.2 | 2.5 |
| (N/20 mm) to | After heating | 3.6 | 2.8 | 2.4 | 2.9 |
| PTFE | treatment at | | | | |
| | 260° C. for 1 minute | | | | |

As Tables 1A and 1B show, compared to Comparative Examples, shrinking of the cured adhesive layers caused by the heating treatment was reduced in Examples. Moreover, in Examples 1 to 3 in which the gel fraction is in the range of 25 to 65 weight %, the adhesive force to PTFE was improved compared to Example 4 in which the gel fraction is out of the above range. In Examples 1 to 3, the adhesive force after the heating treatment was also higher than the initial adhesive force. As FIG. 8 shows, peeling 61 of the cured adhesive layer from the polyimide substrate occurred in Comparative Example 1. The peeling 61 advanced from a perimeter of the sample B to a point indicated by a reference character 62.

### INDUSTRIAL APPLICABILITY

The protective cover member of the present invention can be used, for example, for manufacturing a semiconductor device, such as a MEMS, and/or a circuit board including such a semiconductor device.

1. A protective cover member,
the protective cover member being configured to be placed on a face of an object, the face having an opening, the protective cover member comprising a laminate, wherein
the laminate includes: a protective membrane having a shape configured to cover the opening when the member is placed on the face; and an adhesive agent layer, and
the adhesive agent layer includes a cured adhesive layer of a silicone adhesive agent composition including an addition-curable silicone adhesive agent.

2. The protective cover member according to claim 1, wherein the silicone adhesive agent composition includes the addition-curable silicone adhesive agent as a main component.

3. The protective cover member according to claim 1, wherein the silicone adhesive agent composition does not include a peroxide-curable silicone adhesive agent.

4. The protective cover member according to claim 1, wherein the cured adhesive layer has a gel fraction of 25 to 65 weight %.

5. The protective cover member according to claim 1, wherein the adhesive agent layer and/or the cured adhesive layer is in contact with the protective membrane.

6. The protective cover member according to claim 1, wherein the adhesive agent layer and/or the cured adhesive layer forms a joining surface to be joined to the face of the object.

7. The protective cover member according to claim 1, wherein
the adhesive agent layer includes a first adhesive agent layer and a second adhesive agent layer, and
the laminate includes the first adhesive agent layer positioned on a first principal surface side of the protective membrane and the second adhesive agent layer positioned on a second principal surface side of the protective membrane.

8. The protective cover member according to claim 1, wherein the adhesive agent layer includes an adhesive tape including a substrate and the cured adhesive layer placed on at least one surface of the substrate.

9. The protective cover member according to claim 8, wherein the adhesive tape is a double-sided adhesive tape.

10. The protective cover member according to claim 8, wherein the substrate includes a heat-resistant resin.

11. The protective cover member according to claim 1, wherein the protective membrane has gas permeability in a thickness direction of the protective membrane.

12. The protective cover member according to claim 1, wherein the protective membrane includes a polytetrafluoroethylene membrane.

13. The protective cover member according to claim 1, wherein the protective membrane has an area of 175 mm² or less.

14. The protective cover member according to claim 1, wherein
when viewed perpendicular to a principal surface of the protective membrane,
the adhesive agent layer is placed in a peripheral portion of the protective membrane, and
a ratio L₂/L₁ of a length L₂ of a portion of a shortest line segment of line segments extending from a center of the protective membrane to a perimeter of the protective membrane to a length L₁ of the shortest line segment is 0.3 or less, the portion lying over the adhesive agent layer.

15. The protective cover member according to claim 1, being for a micro electro mechanical system (MEMS).

16. A member supplying sheet comprising:
a substrate sheet; and
at least one protective cover member placed on the substrate sheet, wherein
the protective cover member is the protective cover member according to claim 1.
